(19) United States
(12) Patent Application Publication
(10) Pub. No.: US 2025/0338439 A1
(43) Pub. Date: Oct. 30, 2025

(54) DOUBLE-SIDED COOLING LIQUID COOLING HEAD

(71) Applicant: APALTEK CO., LTD., Shenzhen (CN)

(72) Inventors: Qineng XIAO, Dongguan (CN); Dagao ZHENG, Shenzhen (CN); Jun-Chun QIU, Shenzhen (CN); Chi ZOU, Shenzhen (CN)

(21) Appl. No.: 18/744,546

(22) Filed: Jun. 14, 2024

(30) Foreign Application Priority Data
Apr. 26, 2024 (CN) 2024105220887

(51) Int. Cl. H05K 7/20

(52) U.S. Cl. CPC H05K 7/20272; H05K 7/2039

(57) ABSTRACT

A double-sided cooling-liquid cooling head has a frame, a baffle, a first cover, and a second cover. The frame has two side strips and two connecting strips connected to each other to form an accommodating space. The connecting strips separately has an inlet and an outlet. The baffle is fixed in the frame to separate the accommodating space to a first and a second space. The inlet and the outlet are communicated to the first space and the second space. The first cover is fixed on a side of the frame and has a first fin group located in the first space and abutted against the baffle. The second cover is fixed on another side of the frame and has a second fin group located in the second space and abutted against the baffle. The first cover and the second cover are used to cool two heat sources.

### BACKGROUND

### Technical Field

The present disclosure relates to heat dissipation field, particularly to a double-sided cooling liquid cooling head.

### Description of Related Art

As electronic devices have gradually developed towards thinner, lighter, and high-efficiency in recent years, the electronic devices need to reduce size and weight while improving performance. The electronic devices have increased difficulty of overall heat dissipation design because of higher requirement to heat dissipation due to a large amount of heat generated during achieving high-efficiency and less space to arrange the heat dissipation structure inside the electronic devices. In addition, circuit boards or chips are arranged in parallel within the housing for reducing the size of many electronic devices. An area for arranging circuit or electronic components is therefore increasing, yet leading interference between a plurality of heat dissipation structures.

In view of the above, the inventor seeks to overcome the aforementioned drawbacks associated with the current technology and aims to provide an effective solution through extensive researches along with utilization of academic principles and knowledge.

### SUMMARY

The primary objective of the present disclosure is to dissipate heat from two heat sources at the same time.

To accomplish the aforementioned objective, the present disclosure provides a double-sided cooling liquid cooling head having a frame, a baffle, a first cover, and a second cover. The frame includes a pair of side strips and a pair of connecting strips. The side strips are parallel and opposite to each other. The connecting strips are respectively connected to two ends of each of the side strips. The side strips and the connecting strips jointly form an accommodating space. One of the connecting strips has an inlet. The other connecting strip has an outlet. The baffle is fixed in the frame to separate the accommodating space to a first space and a second space. The inlet is communicated to the first space and the second space. The outlet is communicated to the first space and the second space. The first cover has a first fin group. The first cover is corresponding to the first space and fixed on a side of the frame. The first fin group is located in the first space and abutted against the baffle. The second cover has a second fin group. The second cover is corresponding to the second space and fixed on another side of the frame. The second fin group is located in the second space and abutted against the baffle.

Another aspect of the present disclosure provides that the baffle is connected to the side strips and the connecting strips.

Another aspect of the present disclosure provides that a location of the baffle is corresponding to a center of the inlet.

Another aspect of the present disclosure provides that a location of the baffle is corresponding to a center of the outlet.

Another aspect of the present disclosure provides that the first fin group has a plurality of first heat dissipation channels, the second fin group has a plurality of second heat dissipation channels, two ends of each of the first heat dissipation channels respectively faces to each of the connecting strips, two ends of each of the second heat dissipation channels respectively faces to each of the connecting strips.

Another aspect of the present disclosure provides that the baffle defines a liquid-entry notch and a liquid-exit notch, the liquid-entry notch is communicated to the inlet, the first space, and the second space, the liquid-exit notch is communicated to the outlet, the first space, and the second space.

Another aspect of the present disclosure provides that the first cover has a first flat attached to the frame, the first fin group is convex on the first flat.

Another aspect of the present disclosure provides that the second cover has a second flat attached to the frame, the second fin group is convex on the second flat.

Another aspect of the present disclosure provides that the first cover has a first heat-conduction block, the first heat-conduction block is convex on the first cover along a direction away from the first fin group.

Another aspect of the present disclosure provides that the second cover has a second heat-conduction block, the second heat-conduction block is convex on the second cover along a direction away from the second fin group.

The double-sided cooling liquid cooling head of the present disclosure fixes the baffle in the frame to separate the accommodating space to the first space and the second space, fixes the first cover having the first fin group on a side of the frame corresponding to the first space, and fixes the second cover having the second fin group on another side of the frame corresponding to the second space, whereby the first cover and the second cover may attach different heat sources to achieve the effect for dissipating heat from two heat sources at the same time.

### BRIEF DESCRIPTION OF THE DRAWINGS

FIG. 1 is an exploded view of the present disclosure;

FIG. 2 is a perspective appearance view of the present disclosure;

FIG. 3 is another perspective appearance view of the present disclosure;

FIG. 4 is a cross-sectional top view of the present disclosure in use;

FIG. 5 is a cross-sectional side view of the present disclosure in use; and

FIG. 6 is another cross-sectional side view of the present disclosure in use.

### DETAILED DESCRIPTION

It is to be understood that the terms for indicating positions and the location relation, for example “front”, “rear”, “left”, “right”, “front end”, “rear end”, “distal end”, “longitudinal direction”, “lateral direction”, “vertical direction”, “top” and “bottom”, are based on the positions and the location relation disclosed in the drawings, and only used for disclosing the present disclosure and not used for indicating or implying the specified location of the device or the components or the specified structure and operation in certain location, thus the present disclosure is not intended to be limiting.

For example, the terms of “first”, “second”, “third”, “forth” and “fifth” are used for illustrating each unit, component, area, layer and/or part. The component, the unit, the area, the layer and/or the part are not limited by the terms. These terms are only used for separating the element, the assembly, the area, the layer, or the part. Unless being clearly indicated according to the whole specification, the terms for example “the first”, “the second”, “the third”, “the fourth” and “the fifth” are not used for implying the order or sequence.

The technical contents of the present disclosure will become apparent with the detailed description of embodiments and the accompanied drawings as follows. However, it shall be noted that the accompanied drawings are for illustrative purposes only such that they shall not be used to restrict the scope of the present disclosure.

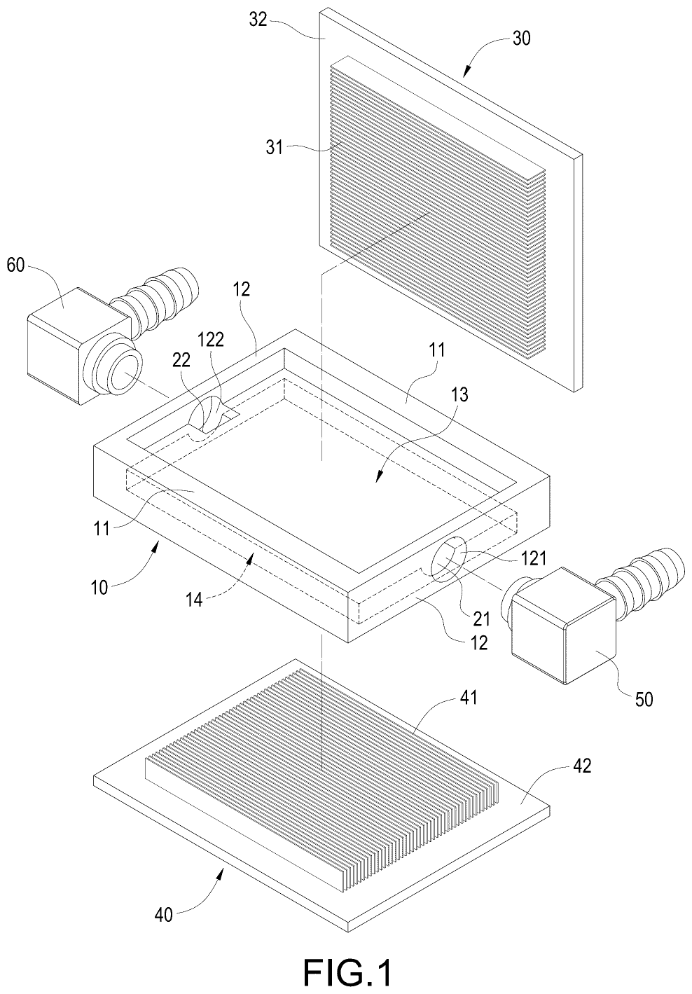

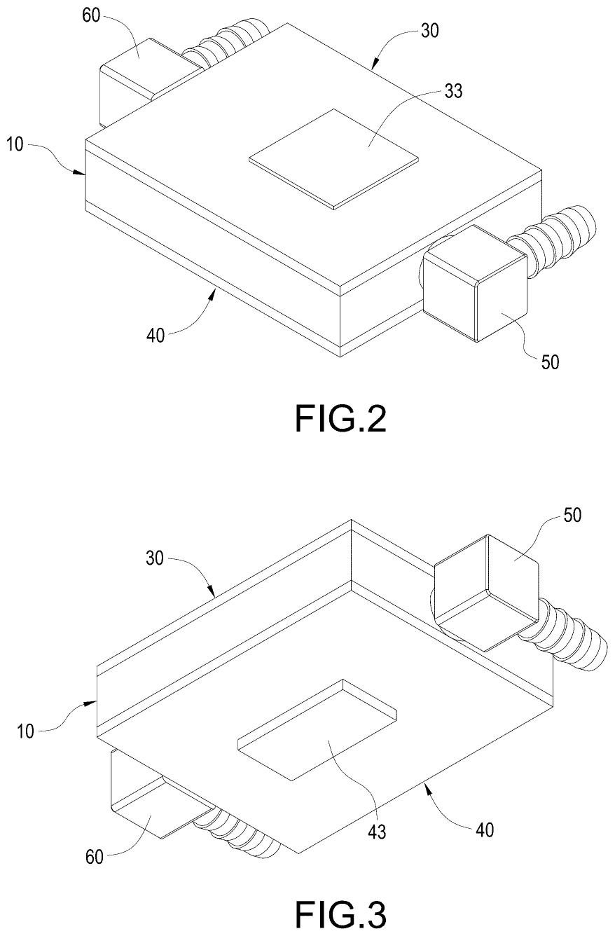

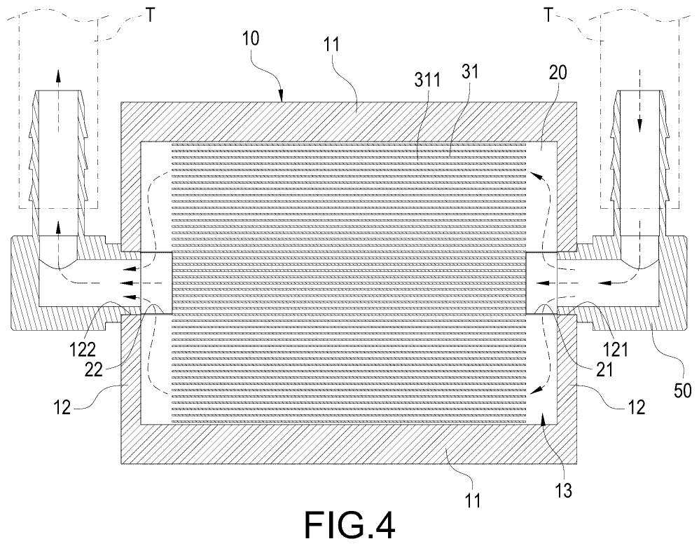

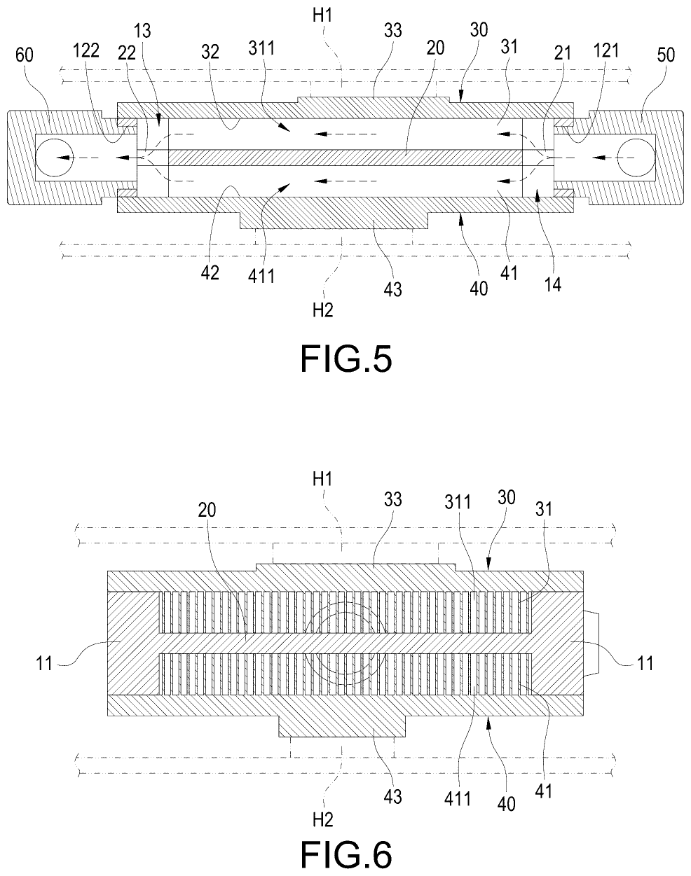

The present disclosure provides a double-sided cooling liquid cooling head, which is used to dissipate heat from two heat sources H1 and H2 at the same time or dissipate heat from one heat source H1/H2. As shown in FIG. 1, FIG. 2, FIG. 3, FIG. 4, FIG. 5, and FIG. 6. The double-sided cooling liquid cooling head of the present disclosure includes a frame 10, a baffle 20, a first cover 30, and a second cover 40.

In the embodiment, the frame 10 includes a pair of side strips 11 and a pair of connecting strips 12. In details, the side strips 11 are parallel and opposite to each other, and the connecting strips 12 are respectively connected to two ends of each of the side strips 11 so that the frame 10 is a rectangular frame structure, but the present disclosure is not limit to this shape. For example, the frame 10 may also be a circle, triangle, polygonal or irregular-shape frame structure. The side strips 11 and the connecting strips 12 jointly form an accommodating space, that is the accommodating space is a cube space. One of the connecting strips 12 has an inlet 121 for inserting and fixing an inlet joint 50. The other connecting strip 12 has an outlet 122 for inserting and fixing an outlet joint 60. As the drawings for example, the inlet 121 in the embodiment is located on the connecting strip 12 in a right side of the drawings, the outlet 122 in the embodiment is located on the connecting strip 12 in a left side of the drawings, but the present disclosure is not limit to this embodiment. The inlet joint 50 and the outlet joint 60 may be separately connected to a liquid-transmission tube T to transfer a coolant (not labeled in figures) into or out the double-sided cooling liquid cooling head of the resent disclosure.

The baffle 20 is fixed in the frame 20 so that the baffle 20 separates the accommodating space to a first space 13 and a second space 14. In detail, four sides of the baffle 20 are respectively connected to the side strips 11 and the connecting strips 12 so as to separate the accommodating space into upper and lower parts in the drawings. A location of the baffle 20 is corresponding to a center of the inlet 121 such that the inlet 121 is communicated to the first space 13 and the second space 14. A location of the baffle 20 is corresponding to a center of the outlet 122 such that the outlet 122 is communicated to the first space 13 and the second space 14. In the embodiment, the baffle 20 defines a liquid-entry notch 21 and a liquid-exit notch 22, but the present disclosure is not limit to this embodiment. The liquid-entry notch 21 is communicated to the inlet 121, the first space 13, and the second space 14, and the liquid-exit notch 22 is communicated to the outlet 122, the first space 13, and the second space 14.

The first cover 30 has a first fin group 31. The first cover 30 is corresponding to the first space 13 and fixed on a side of the frame 10 such that the first fin group 31 is located in the first space 13 and abutted against the baffle 20. In detail, the first cover 30 in the embodiment has a first flat 32 attached to a side of the frame 10, and the first fin group 31 is convex on the first flat 32 to be accommodated in the first space 13 and abut against the baffle 20. That is, the first flat 32 is an inner surface of the first cover 30 in the embodiment, but the present disclosure is not limit to this embodiment. For example, four sides of the first cover 30 may also be connected to inner side of the frame 10 (that is the first cover 30 is connected to the side strips 11 and the connecting strips 12), as long as the first cover 30 is fixed on the side of the frame 10.

The second cover 40 has a second fin group 41. The second cover 40 is corresponding to the second space 14 and fixed on another side opposite to the side of the frame 10 such that the second fin group 41 is located in the second space 14 and abutted against the baffle 20. In detail, the second cover 40 in the embodiment has a second flat 42 attached to the opposite side of the frame 10, and the second fin group 41 is convex on the second flat 42 to be accommodated in the second space 14 and abut against the baffle 20. That is, the second flat 42 is an inner surface of the second cover 40 in the embodiment, but the present disclosure is not limit to this embodiment. For example, four sides of the second cover 40 may also be connected to inner side of the frame 10 (that is the second cover 40 is connected to the side strips 11 and the connecting strips 12), as long as the second cover 40 is fixed on the opposite side of the frame 10.

Details are provided as follows. Please refer FIG. 1, FIG. 4, FIG. 5, and FIG. 6. The first fin group 31 has a plurality of first heat dissipation channels 311, and the second fin group 41 has a plurality of second heat dissipation channels 411. In the embodiment, two ends of each of the first heat dissipation channels 311 respectively faces to each of the connecting strips 12, and two ends of each of the second heat dissipation channels 411 respectively faces to each of the connecting strips 12, but the present disclosure is not limit to this embodiment. The types of locations and shapes of the first fin group 31 and the second fin group 41 may be modified and adjusted according to different needs so as to adjust shapes and directions of the first heat dissipation channels 311 and the second heat dissipation channels 411.

Please refer FIG. 2, FIG. 3, FIG. 5, and FIG. 6. The first cover 30 has a first heat-conduction block 33, and the second cover 40 has a second heat-conduction block 43. The first heat-conduction block 33 is convex on the first cover 30 along a direction away from the first fin group 31, and the second heat-conduction block 43 is convex on the second cover 40 along a direction away from the second fin group 41. Thus, the first heat-conduction block 33 and the second heat-conduction block 43 are convenient to respectively attach the two heat sources H1 and H2 so as to absorb heat generated by the heat sources H1 and H2. In detail, the first heat-conduction block 33 is convex on an outer side of the first cover 30 and located on a side opposite to the first fin group 31, and the second heat-conduction block 43 is convex on an outer side of the second cover 40 and located on a side opposite to the second fin group 41.

Please refer FIG. 4, FIG. 5, and FIG. 6. The coolant enters the inlet joint 50 through the liquid-transmission tube T, and then pass the inlet 121 and the liquid-entry notch 21 of the baffle 20 so as to disperse up and down into the first space 13 and the second space 14. The coolant passes through the first heat dissipation channels 311 of the first fin group 31 and the second heat dissipation channels 411 of the second fin group 41 so as to take away the heat that the first heat-conduction block 33 and the second heat-conduction block 43 absorb from the heat sources H1 and H2 and dissipate heat by passing the coolant through the first heat dissipation channels 311 and the second heat dissipation channels 411. The coolant is confluent at the liquid-exit notch 22 of the baffle 20 from the first space 13 and the second space 14, and then the coolant passes the outlet 122 into the outlet joint 60 to leave from the liquid-transmission tube T. As a result, the baffle 20 separate the accommodating space to the first space 13 and the second space 14 so that the coolant flows independently without interfering with each other after entering the first space 13 and the second space 14. The coolant is therefore dissipating heat absorbed by the first heat-conduction block 33 and the second heat-conduction block 43 such that the double-sided cooling liquid cooling head of the present disclosure may achieve the effect for dissipating heat from two heat sources H1 and H2.

The double-sided cooling liquid cooling head of the present disclosure fixes the baffle 20 in the frame 10 to separate the accommodating space to the first space 13 and the second space 14, fixes the first cover 30 having the first fin group 31 on a side of the frame 10 corresponding to the first space 13, and fixes the second cover 40 having the second fin group 41 on another side of the frame 10 corresponding to the second space 14, whereby the first cover 30 and the second cover 40 may attach different heat sources H1 and H2 to achieve the effect for dissipating heat from two heat sources H1 and H2 at the same time.

It shall be understood that the present disclosure may have other types of embodiments, and a person with ordinary skills in the art of the technical field of the present disclosure may make various changes and modifications corresponding to the present disclosure without deviating the principle and substance of the present disclosure; however, such corresponding changes and modification shall be considered to be within the claimed scope of the present disclosure.

What is claimed is:

1. A double-sided cooling liquid cooling head, comprising:
A frame, comprising a pair of side strips and a pair of connecting strips, the side strips parallel and opposite to each other, the connecting strips respectively connected to two ends of each of the side strips, the side strips and the connecting strips jointly forming an accommodating space, one of the connecting strips comprising an inlet, the other connecting strip comprising an outlet,
a baffle, fixed in the frame to separate the accommodating space to a first space and a second space, wherein the inlet communicated to the first space and the second space, the outlet communicated to the first space and the second space;
a first cover, comprising a first fin group, the first cover corresponding to the first space and fixed on a side of the frame, the first fin group located in the first space and abutted against the baffle; and
a second cover, comprising a second fin group, the second cover corresponding to the second space and fixed on another side of the frame, the second fin group located in the second space and abutted against the baffle.

2. The double-sided cooling liquid cooling head according to claim 1, wherein the baffle is connected to the side strips and the connecting strips.

3. The double-sided cooling liquid cooling head according to claim 1, wherein a location of the baffle is corresponding to a center of the inlet.

4. The double-sided cooling liquid cooling head according to claim 1, wherein a location of the baffle is corresponding to a center of the outlet.

5. The double-sided cooling liquid cooling head according to claim 1, wherein the first fin group comprises a plurality of first heat dissipation channels, the second fin group comprises a plurality of second heat dissipation channels, two ends of each of the first heat dissipation channels respectively faces to each of the connecting strips, two ends of each of the second heat dissipation channels respectively faces to each of the connecting strips.

6. The double-sided cooling liquid cooling head according to claim 1, wherein the baffle comprises a liquid-entry notch and a liquid-exit notch, the liquid-entry notch is communicated to the inlet, the first space, and the second space, the liquid-exit notch is communicated to the outlet, the first space, and the second space.

7. The double-sided cooling liquid cooling head according to claim 1, wherein the first cover comprises a first flat attached to the frame, the first fin group is convex on the first flat.

8. The double-sided cooling liquid cooling head according to claim 1, wherein the second cover comprises a second flat attached to the frame, the second fin group is convex on the second flat.

9. The double-sided cooling liquid cooling head according to claim 1, wherein the first cover comprises a first heat-conduction block, the first heat-conduction block is convex on the first cover along a direction away from the first fin group.

10. The double-sided cooling liquid cooling head according to claim 1, wherein the second cover comprises a second heat-conduction block, the second heat-conduction block is convex on the second cover along a direction away from the second fin group.
